(19) United States
(12) Patent Application Publication
(10) Pub. No.: US 2015/0084130 A1
(43) Pub. Date: Mar. 26, 2015

(54) SEMICONDUCTOR STRUCTURE AND METHOD FOR MANUFACTURING THE SAME

(71) Applicants: Haizhou Yin, Poughkeepsie, NY (US); Huilong Zhu, Poughkeepsie, NY (US); Zhijiong Luo, Poughkeepsie, NY (US)

(72) Inventors: Haizhou Yin, Poughkeepsie, NY (US); Huilong Zhu, Poughkeepsie, NY (US); Zhijiong Luo, Poughkeepsie, NY (US)

(73) Assignee: Institute of Microelectronics, Chinese Academy of Sciences, Beijing (CN)

(21) Appl. No.: 14/397,558

(22) PCT Filed: May 16, 2012
(86) PCT No.: PCT/CN2012/075605

§ 371 Date: Oct. 28, 2014

(30) Foreign Application Priority Data
Apr. 28, 2012 (CN) 201210134605.0

(51) Int. Cl. H01L 29/78; H01L 21/02; H01L 21/762; H01L 27/12; H01L 29/66

(52) U.S. Cl. CPC H01L 29/7841; H01L 27/1203; H01L 29/6656; H01L 21/76264; H01L 21/02532
USPC 257/348; 438/151

(57) ABSTRACT

The present invention provides a method for manufacturing a semiconductor structure, which comprises following steps: providing an SOI substrate, onto which a heavily doped buried layer and a surface active layer are formed; forming a gate stack and sidewall spacers on the substrate; forming an opening at one side of the gate stack, wherein the opening penetrates through the surface active layer, the heavily doped buried layer and reaches into a silicon film located on an insulating buried layer of the SOI substrate; filling the opening to form a plug; forming source/drain regions, wherein the source region overlaps with the heavily doped buried layer, and a part of the drain region is located in the plug. Accordingly, the present invention further provides a semiconductor structure. In the present invention, the heavily doped buried layer is favorable for reducing width of depletion layers at source/drain regions and suppressing short-channel effects. The heavily doped buried layer overlaps with the source region, which thence forms a heavily doped pn junction favorable for suppressing floating body effects of SOI MOS devices, thereby improving performance of semiconductor devices. Besides, no body contact is needed in the present invention, thus device area and manufacturing cost are saved.

The present application claims priority benefit of Chinese patent application No. 201210134605.0, filed on 28 Apr. 2012, entitled “SEMICONDUCTOR STRUCTURE AND METHOD FOR MANUFACTURING THE SAME”, which is herein incorporated by reference in its entirety.

### FIELD OF THE INVENTION

The present invention relates to semiconductor manufacturing field, particularly, to a semiconductor structure and a method for manufacturing the same.

### BACKGROUND OF THE INVENTION

In order to improve both performance and integrity of integrated circuit chips, feature sizes of devices are scaled down continually in view of Moore's law, which nowadays have already reached into the nanometer regime. However, power consumption and electric current leakage become the most concerned issues along with downscaling in dimension of devices. Accordingly, Silicon on Insulator (SOI) architectures have become preferred structures for deep sub-micrometer or nanometer MOS devices, owing to various advantages like high operation speed, low power consumption, high integrity, good anti-radiation and absence of self-locking effects. SOI MOS devices are classified into two types, i.e., partially depleted and fully depleted, with respect to the ratio of the thickness of a silicon film to the maximum thickness of a surface depletion layer. Fully depleted SOI MOS has a relatively thin top layer of Si film, and its SOI substrate costs relatively high; therefore, partially depleted SOI MOS is still the one widely used nowadays.

In a partially depleted SOI MOS device, the maximum thickness of a surface depletion layer is smaller than the thickness of a top layer of Si film, such that the body region thereof is suspended, the strong electric field at drain accelerates carriers in channels, which thence gives rise to impact ionization and generates electron-hole pairs. The newly produced electron-hole pairs are separated forced by strong electric field, then electrons are collected by drain, while holes aggregate in the substrate near the drain and the buried oxide layer, consequently, floating body effects (FBE) arise therefrom. Floating body effects cause electric charges to aggregate at body region, which thence gives rise to increase in electric potentials, such that MOS device will experience a decrease in threshold voltage and an increase in output electric current, namely, Kink effects. Besides, floating body effects further cause problems in device performance and reliability, such as abnormal sub-threshold slope changes, decrease in source/drain breakdown voltage. Therefore, occurrence of floating body effects should be avoided to an as far extent as possible when devices are designed and manufactured. Nowadays, the conventional method for suppressing floating body effects is to connect a body region with a constant electric potential (source or ground) by a body contact, so as to provide a discharge path for electric charges aggregated at the body region, thereby reducing electric potentials at the body region. However, aforementioned method increases complexity of manufacturing process, results in other parasite effects and even enlarges circuit area.

As channel lengths of Metal-Oxide-Semiconductor Field-Effect Transistors (MOSFET) are continually shortened, short-channel effects (SCE) now become increasingly remarkable and even become dominant factors that unfavorably affect performance of devices. Electrical properties of devices are deteriorated because of short-channel effects; for example, short-channel effects may cause decrease in gate threshold voltage, increase in power consumption and reduction of Signal-to-Noise Ratio (SNR). Accordingly, in order to alleviate short-channel effects, Super-Steep Retrograde Wells (SSRW) are now introduced into semiconductor FET devices. SSRW has low-high-low (or low-high) channel doping profile, that is, surface regions of channels have a low doping concentration, while highly doped regions are formed within regions beneath the channel surfaces through ion implantation or a method as appropriate, so as to reduce width of depletion layers at source/drain regions and, meanwhile, to suppress short-channel effects like increase in leakage current arising from source/drain punch through and increase in threshold voltage. The U.S. Pat. No. 7,002,214 has already disclosed ultra-thin body super-steep retrograde well (SSRW) FET devices. As shown in FIG. 1, heavily doped regions 33L/33R are formed on SOI film through ion implantation, then ultra-thin intrinsic epitaxial regions 48L/48R are grown, so as to form super-steep retrograde doped channel profile and further to form an FET device. However, as shown in the Figures, source/drain regions are in contact with SSRW regions, which thence form heavily doped pn junction that has relatively high junction leakage current, especially at drain; and high junction leakage current affects performance of semiconductor devices.

### SUMMARY OF THE INVENTION

The present invention is intended to at least resolve aforementioned problems; and the present invention provides a semiconductor structure and a method for manufacturing the same, which are favorable for suppressing short-channel effects and floating body effects in SOI MOS devices.

In order to fulfill aforementioned objects, the present invention provides a method for manufacturing a semiconductor structure, which comprises following steps:
(a) providing an SOI substrate, onto which a heavily doped buried layer and a surface active layer are formed;
(b) forming a gate stack and sidewall spacers on the substrate;
(c) forming an opening at one side of the gate stack, wherein the opening penetrates through the surface active layer, the heavily doped buried layer and reaches into a silicon film located on an insulating buried layer of the SOI substrate;
(d) filling the opening to form a plug;
(e) forming source/drain regions, wherein the source region overlaps with the heavily doped buried layer, and a part of the drain region is located in the plug.

In another aspect, the present invention further provides a semiconductor structure, which comprises an SOI substrate, a heavily doped buried layer, a surface active layer, a gate stack, sidewall spacers, a source region and a drain region, wherein:

the SOI substrate comprises upwards in order a base layer, an insulating buried layer and a silicon film;

the heavily doped buried layer is located on the silicon film and under the source region and the gate stack;

the surface active layer is located on the heavily doped buried layer;

the gate stack is located on the surface active layer;

the sidewall spacers at located on sidewalls of the gate stack;

the source region and the drain region, which are embedded into the surface active layer, are located on both sides of the gate stack, wherein the source region overlaps with the heavily doped buried layer.

As compared to the prior art, the present invention exhibits following advantages:

It is favorable for reducing width of depletion layers at source/drain regions and further suppressing short-channel effects through forming a heavily doped buried layer in a substrate and introducing a Super-Steep Retrograde Well (SSRW) to the device; in another aspect, the present invention provides discharge path for body electric charges through connecting the source region with the heavily doped buried layer, which also effectively suppresses floating body effects of SOI semiconductor devices without building a body contact, thereby further saving device area and cost.

### BRIEF DESCRIPTION OF THE DRAWINGS

Aforementioned and/or additional aspects and advantages of the present invention are made more evident according to perusal of the following detailed description of exemplary embodiment(s) in conjunction with accompanying drawings; wherein:

FIG. 1 illustrates a diagram of a semiconductor structure of the U.S. Pat. No. 7,002,214;

FIG. 2 illustrates a diagram of an embodiment of a method for manufacturing a semiconductor structure provided by the present invention;

FIG. 3 to FIG. 14 illustrate respectively cross-sectional views of a semiconductor structure manufactured according to the method for manufacturing a semiconductor structure as illustrated by FIG. 2.

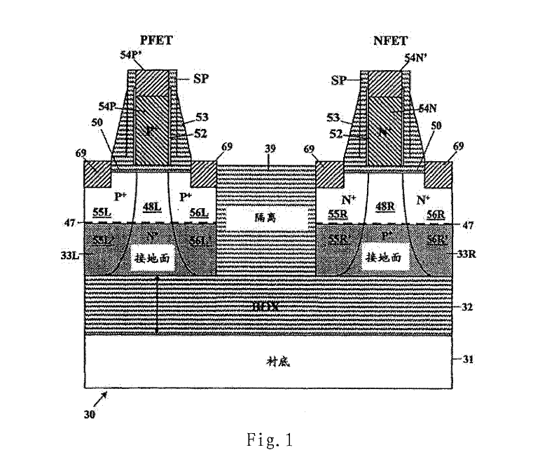

### DETAILED DESCRIPTION OF THE INVENTION

Embodiments of the present invention are described at length below, wherein examples of the embodiments are illustrated in the drawings, in which same or similar reference signs throughout denote same or similar elements or elements have same or similar functions. It should be appreciated that embodiments described below in conjunction with the drawings are illustrative, and are provided for explaining the prevent invention only, thus shall not be interpreted as a limit to the present invention. Various embodiments or examples are provided here below to implement different structures of the present invention. To simplify the disclosure of the present invention, descriptions of components and arrangements of specific examples are given below. Of course, they are only illustrative and not limiting the present invention. Moreover, in the present invention, reference numbers and/or letters may be repeated in different examples. Such repetition is for purposes of simplicity and clarity, yet does not denote any relationship between respective embodiments and/or arrangements under discussion. Furthermore, the present invention provides various examples for various processes and materials. However, it is obvious for a person of ordinary skill in the art that other processes and/or materials may be alternatively utilized. In addition, following structures where a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other.

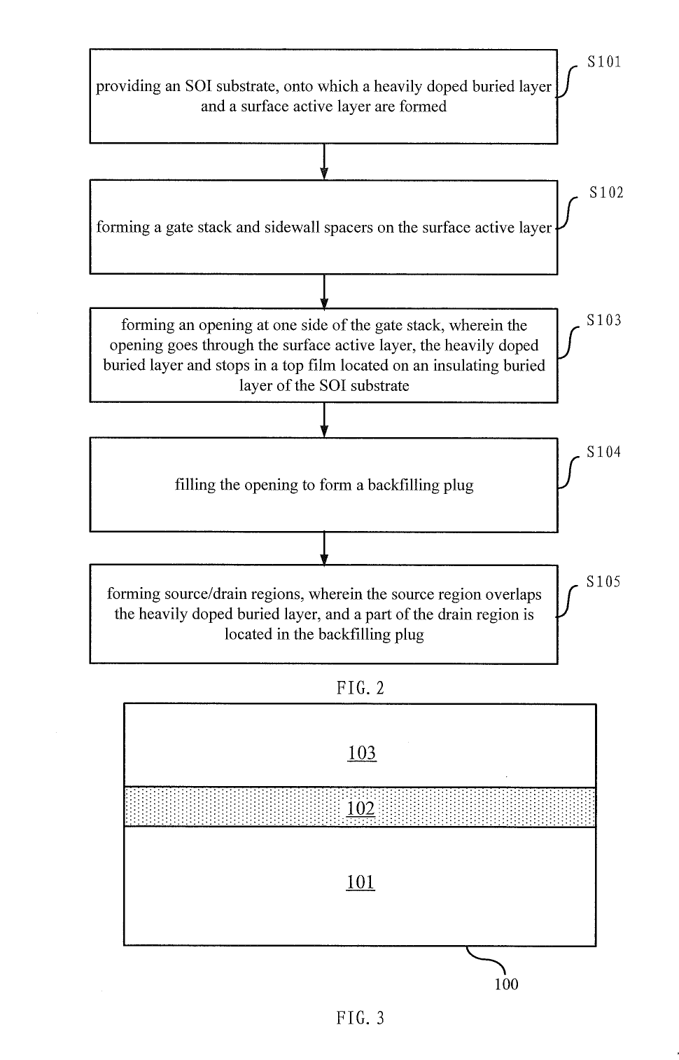

FIG. 2 illustrates a diagram of a method for manufacturing a semiconductor structure provided by the present invention; FIG. 3 to FIG. 14 illustrate respectively cross-sectional views of a semiconductor structure manufactured according to the method for manufacturing a semiconductor structure as illustrated in FIG. 2. Here below, the method for manufacturing a semiconductor structure as illustrated in FIG. 2 is described in depth in conjunction with FIG. 3 to FIG. 14. However, it is noteworthy that the respective figures for embodiments of the present invention are provided for purposes of illustration, thus are not necessarily drawn to scale.

With reference to FIG. 2, FIG. 3 and FIG. 4, step S101 is implemented to provide an SOI substrate 100, onto which a heavily doped buried layer 104 and a surface active layer 105 are formed. The SOI substrate comprises upwards in order a base layer 101, an insulating buried layer 102 and a silicon film 103.

In the present embodiment, the base layer 101 is monocrystalline Si. In other embodiments, the base layer 101 may further comprise other basic semiconductor, such as germanium. Alternatively, the base layer 101 may further comprise compound semiconductors, such as SiC, GaAs, InAs or InP. Typically, the thickness of the base layer 101 may be, but is not limited to, approximately several hundred micrometers, for example, in the range of 0.1 mm-1.5 mm.

The insulating buried layer 102 may be made of an insulating material selected from SiO₂, Si₃N₄ or any other material as appropriate. Typically, the thickness of the insulating buried layer 102 is in the range of 100 nm-300 nm.

The silicon film 103 may be any one of the semiconductor materials used for manufacturing the base layer 101. In the present embodiment, the silicon film 103 is monocrystalline Si. In other embodiments, the silicon film 103 may further comprise other basic semiconductors or compound semiconductors. Typically, the thickness of the silicon film 103 is 10 nm-100 nm.

The heavily doped buried layer 104 may be formed within the silicon film 103 through ion implantation, or may be formed in the Si film 103 at a certain depth through regulating dose, voltage, energy or the like parameter of ion implantation; the surface of the silicon film 103 functions as the surface active layer 105; additionally, the heavily doped buried layer 104 may be further formed above the silicon film 103 through epitaxial process, and configure a doping profile through in-situ doping. The material of the heavily doped buried layer 104 may be Si, Ge or SiGe, and the doping concentration may be 10¹⁸-10²⁰ cm⁻³. The heavily doped buried layer 104 is P-type doped for NMOS and N-type doped for PMOS.

The surface active layer 105 may be formed on the heavily doped buried layer 104 through in-situ doping epitaxial process. Alternatively, during formation of the heavily doped buried layer 104 through ion implantation, parameters like energy, voltage and power consumption for ion implantation are controlled, such that the heavily doped buried layer 104 is formed within the silicon film 103 at a certain depth, thence the surface layer of the silicon film 103 forms the surface active layer 105. The material of the surface active layer 105 may be Si, Ge or SiGe, and the doping concentration may be 10¹⁵-10¹⁸ cm⁻³. The surface active layer 105 is P-type doped for NMOS and N-type doped for PMOS.

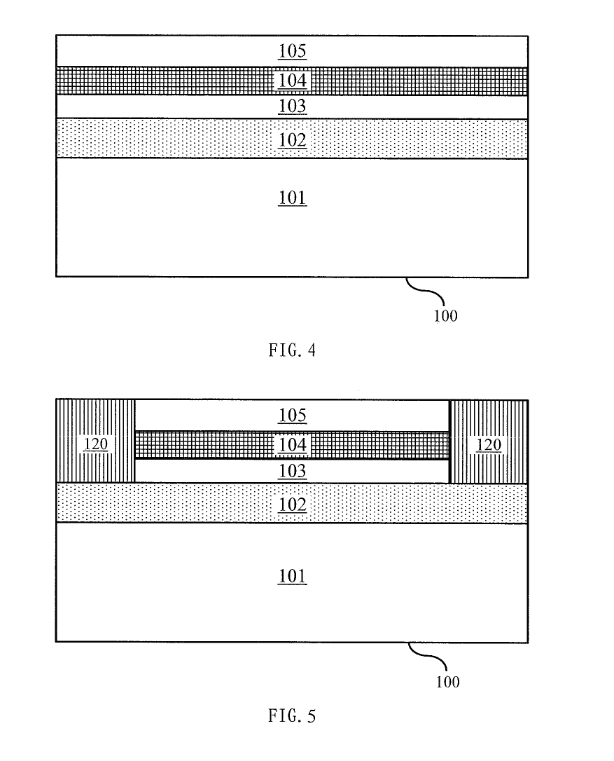

Particularly, step S101 is further comprised of forming an isolation region in the substrate 100, for example, a shallow trench isolation (STI) structure 120, so as to electrically isolate consecutive semiconductor devices. As shown in FIG. 5, the shallow trench isolation (STI) structure 120 penetrates through the surface active layer 105, the heavily doped buried layer 104 and the silicon film 103 till it comes into contact with the insulating buried layer 102, although it may go further through the insulating buried layer 102.

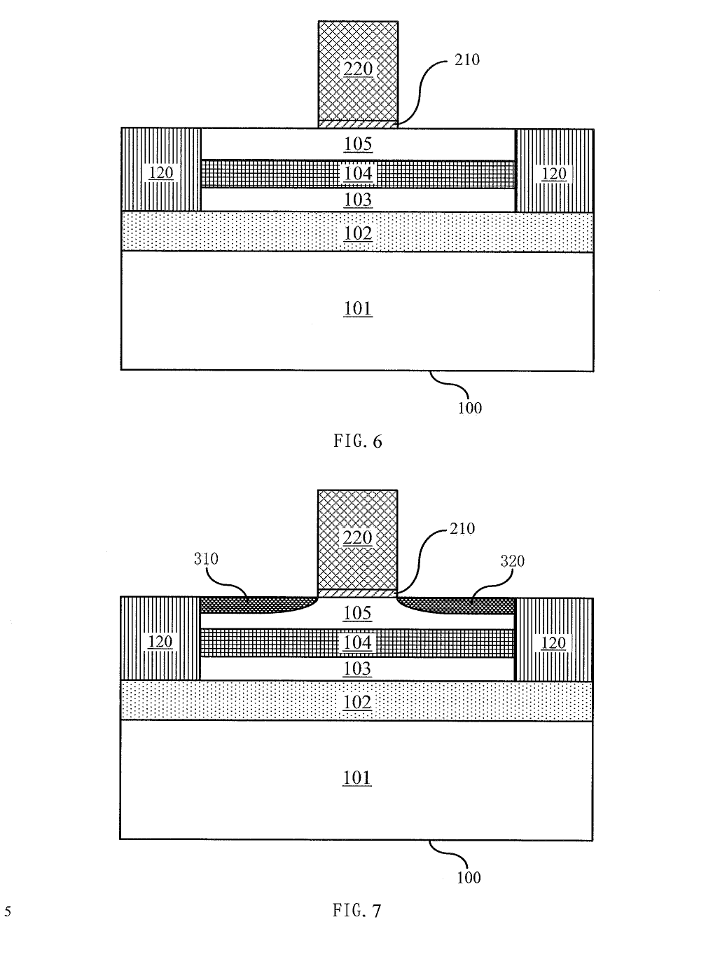

With reference to FIG. 2, FIG. 6-FIG. 8, step S102 is implemented to form a gate stack and sidewall spacers 230 on the substrate 100.

Firstly, as shown in FIG. 6, a gate stack is formed on the substrate, wherein the gate stack comprises a gate dielectric layer 210 and a gate 220. Optionally, the gate stack may further comprise a cap layer (not shown) that covers the gate and is formed through depositing Si₃N₄, SiO₂, SiOₓN_{y}, SiC or combinations thereof, for purpose of protecting the head region of the gate 220 and preventing the same from damage arising from subsequent process. The gate dielectric layer 210 is located on the surface active layer 105 of the substrate 100, and may be made of a High-K dielectric, for example, any one selected from a group consisting of HfO₂, HfSiO, HfSiON, HfTaO, HfTiO, HfZrO, Al₂O₃, La₂O₃, ZrO₂, LaAlO or combinations thereof. In another embodiment, the gate dielectric layer 210 may further be a thermal oxide layer, comprising SiO₂ or SiOₓN_{y}; the thickness of the gate dielectric layer 210 may be 1 nm-10 nm, for example, 5 nm or 8 nm. Then, the gate 220 is formed on the gate dielectric layer 210; wherein the gate 220 may be heavily doped poly Si formed through deposition, or, may be formed through forming a work function metal layer firstly (for NMOS, which is TaC, TiN, TaTbN, TaErN, TaYbN, TaSiN, HfSiN, MoSiN, RuTaₓ, NiTaₓ, etc; for PMOS, which is MoNₓ, TiSiN, TiCN, TaAlC, TiAlN, TaN, PtSiₓ, Ni₃Si, Pt, Ru, Ir, Mo, HfRu, RuOₓ), whose thickness may be 1 nm-20 nm, for example, 3 nm, 5 nm, 8 nm, 10 nm, 12 nm or 15 nm; then, the gate 220 is formed through forming a heavily doped poly Si, Ti, Co, Ni, Al, W or alloy thereof onto the work function metal layer.

In some other embodiments of the present invention, Gate Last process may be used as well; in this case, the gate stack comprises a gate 220 (which is a dummy gate in this case) and a gate dielectric layer 210 for carrying said gate. The gate 220 (which is a dummy gate in this case) is formed on the gate dielectric layer 210 through depositing, for example, poly Si, poly SiGe, amorphous Si, doped or undoped SiO₂, Si₃N₄, SiOₓN_{y}, SiC and even a metal; the thickness of the gate 220 may be 10 nm-80 nm. Optionally, aforesaid process may further comprise forming a cap layer on the gate 220 (which is a dummy gate in this case) through depositing Si₃N₄, SiO₂, SiOₓN_{y}, SiC or combinations thereof, for purpose of protecting the head region of the dummy gate 220 and preventing the head region of the gate 220 (which is a dummy gate in this case) from reacting with metal layers deposited for formation of contact layers in subsequent steps. In another embodiment of Gate Last Process, a gate stack may be formed without a gate dielectric layer 210 at first; instead, at the subsequent processing steps, a gate dielectric layer 210 may be formed after removal of the dummy gate yet prior to filling the work function metal layer.

Optionally, as shown in FIG. 7, after formation of the gate stack, aforesaid process further comprises implanting P-type or N-type dopants into the surface active layer 105 with the gate stack functioning as a mask, so as to form source/drain extension regions 310 and 320 on both sides of the gate stack. The source extension region 310 and the drain extension region 320 may be P-type doped Si for PMOS and N-type doped Si for NMOS. Then, the semiconductor structure experiences annealing so as to activate dopants in the source extension region 310 and the drain extension region 320; wherein annealing may be performed through rapid annealing, spike annealing or any other method as appropriate.

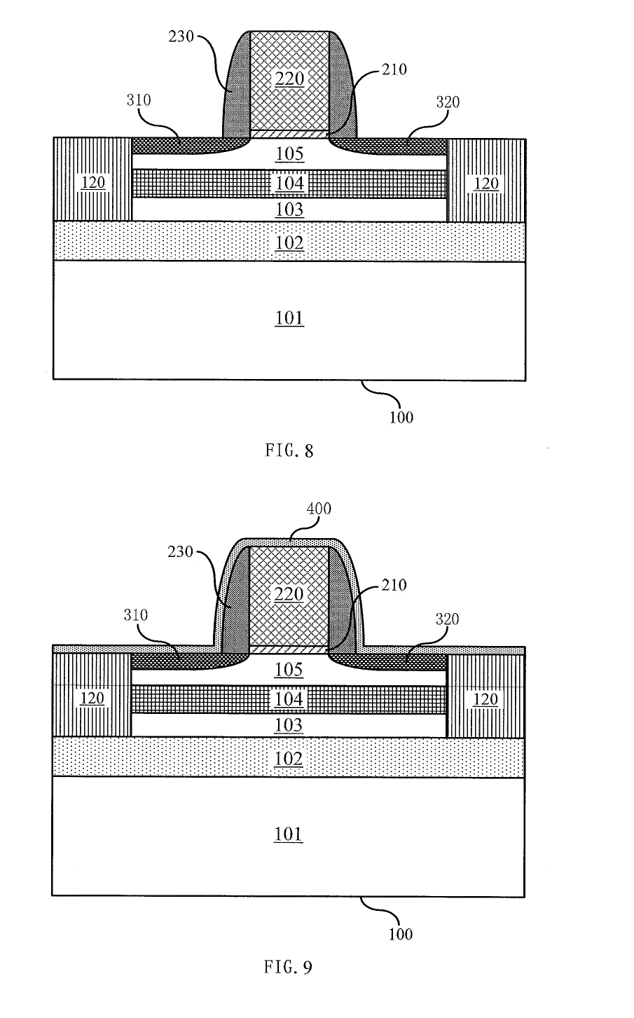

As shown in FIG. 8, sidewall spacers 230 are formed on sidewalls of the gate stack for isolating the gate stack. The sidewall spacers 230 may be made of a material selected from a group consisting of Si₃N₄, SiO₂, SiOₓN_{y} and SiC or combinations thereof, and/or other materials as appropriate. The sidewall spacers 230 may be in a multi-layer structure. The sidewall spacers 230 may be formed through deposition-etching process, and the thickness thereof may be in the range of 10 nm-100 nm, for example, 30 nm, 50 nm or 80 nm.

With reference to FIG. 9-FIG. 11, step S103 is implemented to form an opening 500 on one side of the gate stack. The opening 500 penetrates through the surface active layer 105, the heavily doped buried layer 104 and reaches into the silicon film 103 of the SOI substrate 100.

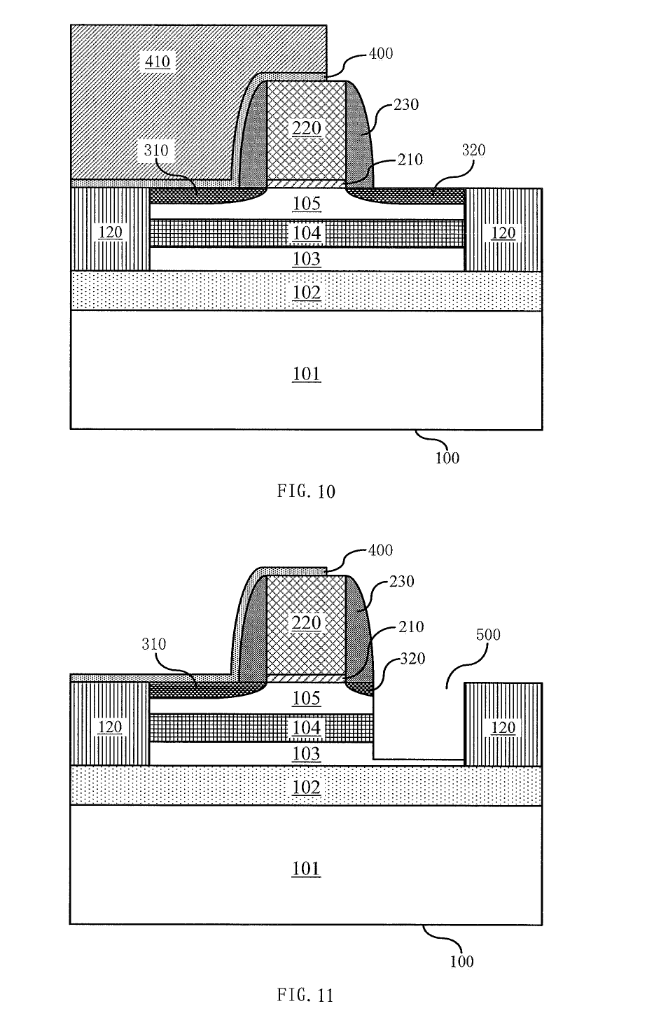

Firstly, as shown in FIG. 9, a mask layer 400 is formed on the substrate 100; the material of the mask layer 400 may be SiO₂, Si₃N₄ or SiOₓN_{y}, and the mask layer 400 may be formed by means of chemical vapor deposition (CVD), sputtering or any other method as appropriate. Then, as shown in FIG. 10, a layer of photoresist 410 is formed to cover the mask layer 400, then the photoresist 410 is patterned by means of exposure and development, then the mask layer 400 is etched to expose a part of the surface active layer 105 on one side of the gate stack. And then, as shown in FIG. 11, the opening 500, which penetrates through the surface active layer 105, the heavily doped buried layer 104 and reaches into the silicon film 103, is formed through dry RIE etching or wet etching; at last, the photoresist 410 is removed.

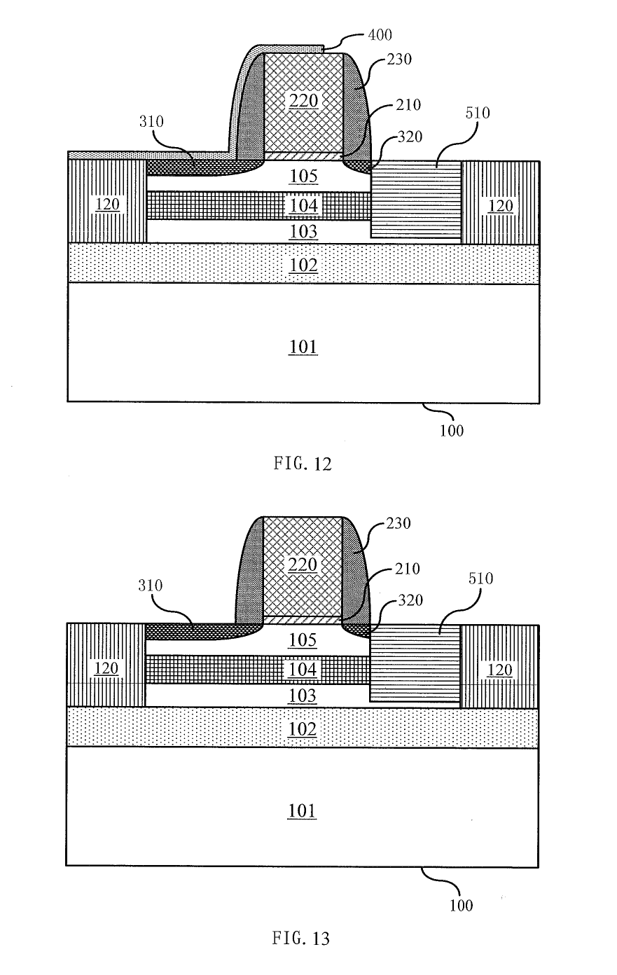

With reference to FIG. 12 and FIG. 13, step S104 is implemented to fill the opening 500 so as to form a plug 510. The opening 500 may be filled through epitaxial method, and the materials of the plug may be Si, Ge or SiGe. Optionally, at the process of filling the opening, the opening 500 may be filled at first from the epitaxial portion, so as to make it higher than the heavily doped buried layer 104; then, in-situ doping epitaxy is performed to fill the opening completely and to form a drain region. The plug 510 may be higher than the surface active layer 105, which hence is favorable for formation of a raised drain region and reducing series resistance at the drain region. Finally, the mask layer 400 is removed, as shown in FIG. 13.

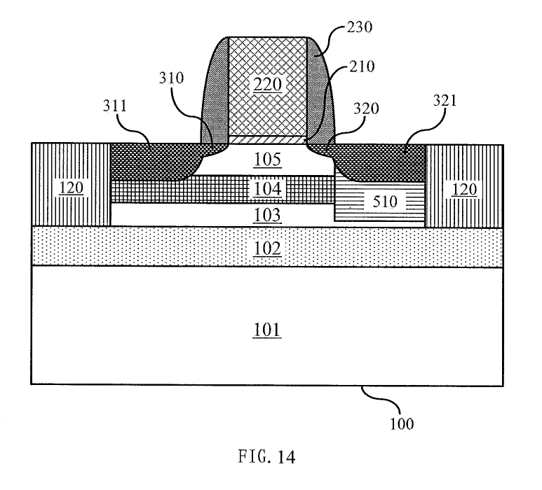

With reference to FIG. 14, step S105 is implemented to form a source region 311 and a drain region 321. P-type or N-type dopants are implanted into the substrate with the gate stack and sidewall spacers 230 functioning as masks, so as to form the source region 311 and the drain region 321. The source region 311 and the drain region 321 are P-type doped for PMOS and N-type doped for NMOS. Then, the semiconductor structure experiences annealing so as to activate dopants in the source region 311 and the drain region 321. Wherein annealing may be performed through rapid annealing, spike annealing or any other method as appropriate. The source region 311 overlaps with the heavily doped buried layer 104 to form a heavily doped pn junction and thence to raise relatively great junction leakage current, which is favorable for suppressing floating body effects. A part of the drain region 321 is located in the plug 510.

The manufacturing of the semiconductor structure is completed according to steps of conventional process for manufacturing semiconductors; for example, forming a metal silicide on the source/drain regions; depositing an interlayer dielectric layer to cover the source/drain regions and the gate stack; etching the interlayer dielectric layer to expose the source/drain regions so as to form contact vias; filling the contact vias with metal; and forming multiple metal interconnecting layers in subsequent processes and steps. Alternatively, in a Gate Replacement process, steps like removing a dummy gate to form a metal gate may be implemented as well.

The present invention further provides a semiconductor structure, which comprises an SOI substrate 100, a heavily doped buried layer 104, a surface active layer 105, a gate stack, sidewall spacers 230, a source region 311 and a drain region 321, as shown in FIG. 14; wherein, the SOI substrate 100 comprises upwards in order a base layer 101, an insulating buried layer 102 and a silicon film 103. The heavily doped buried layer 104 is located on the silicon film 103 and under the source region 311 and the gate stack; the surface active layer 105 is located on the heavily doped buried layer 104; the gate stack is located on the surface active layer 105; the sidewall spacers 230 are located on sidewalls of the gate stack; the source region 311 and the drain region 321, which are embedded into the surface active layer 105, are located on both sides of the gate stack, wherein the source region 311 overlaps with the heavily doped buried layer 104. The materials of the surface active layer 105 may be Si, Ge or SiGe, and the doping concentration may be 10¹⁵-10¹⁸ cm⁻³. The surface active layer 105 is P-type doped for NMOS and N-type doped for PMOS. The materials of the heavily doped buried layer 104 may be Si, Ge or SiGe, and the doping concentration may be 10¹⁸-10²⁰ cm⁻³; The heavily doped buried layer 104 is P-type doped for NMOS and N-type doped for PMOS. The heavily doped buried layer 104 configures retrograde well in the substrate, which thence is favorable for reducing width of a depletion layer at the source region and suppressing short-channel effects. Connection of the heavily doped buried layer 104 to the source region 311 forms a heavily doped pn junction, which raises relatively great junction leakage current, provides a discharge path for electric charges at the body region, and effectively suppresses floating body effects occurring to semiconductor devices; meanwhile, no body contact is needed, thus device area and manufacturing cost are saved accordingly.

Although the exemplary embodiments and their advantages have been described at length herein, it should be understood that various alternations, substitutions and modifications may be made to the embodiments without departing from the spirit of the present invention and the scope as defined by the appended claims. As for other examples, it may be easily appreciated by a person of ordinary skill in the art that the order of the process steps may be changed without departing from the scope of the present invention.

In addition, the scope, to which the present invention is applied, is not limited to the process, mechanism, manufacture, material composition, means, methods and steps described in the specific embodiments in the specification. According to the disclosure of the present invention, a person of ordinary skill in the art should readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

1. A method for manufacturing a semiconductor structure, comprising:
(a) providing an SOI substrate, on which a heavily doped buried layer and a surface active layer are formed;
(b) forming a gate stack and sidewall spacers on the substrate;
(c) forming an opening on one side of the gate stack, wherein the opening penetrates through the surface active layer, the heavily doped buried layer and reaches into a silicon film located on an insulating buried layer of the SOI substrate;
(d) filling the opening to form a plug; and
(e) forming source/drain regions, wherein the source region overlaps with the heavily doped buried layer, and a part of the drain region is located in the plug.

2. The method of claim 1, wherein at step (a), the method for forming the heavily doped buried layer is ion implantation or performing in-situ doping epitaxy on the silicon film of the SOI substrate.

3. The method of claim 1, wherein at step (a), the method for forming the surface active layer is performing in-situ doping epitaxy on the heavily doped buried layer.

4. The method of claim 1, wherein at step (a), the materials of the heavily doped buried layer are Si, Ge or SiGe, and the doping concentration is 10¹⁸-10²⁰ cm⁻³, and the heavily doped buried layer is P-type doped for NMOS and N-type doped for PMOS.

5. The method of claim 1, wherein at step (a), the materials of the surface active layer are Si, Ge or SiGe, and the doping concentration is 10¹⁵-10¹⁸ cm⁻³, and the surface active layer is P-type doped for NMOS and N-type doped for PMOS.

6. The method of claim 1, wherein at step (c), the step for forming the opening comprises:
(i) forming a mask layer to cover the gate stack and the substrate;
(ii) etching the mask layer to expose a part of the surface active layer on one side of the gate stack; and
(iii) etching to form the opening that penetrates through the surface active layer, the heavily doped buried layer and reaches into the silicon film on the insulating layer of the SOI substrate.

7. The method of claim 1, wherein, at step (d), the method for filling the opening is an epitaxial process.

8. The method of claim 1, wherein step (d) further comprises filling the opening by an epitaxial process so that the opening is higher than the heavily doped buried layer, and then performing in-situ doping epitaxy to form the drain region.

9. The method of claim 1, wherein at step (d), the materials of the plug are Si, Ge or SiGe.

10. A semiconductor structure comprising an SOI substrate, a heavily doped buried layer, a surface active layer, a gate stack, sidewall spacers, a source region and a drain region, wherein,
the SOI substrate comprises, from bottom to top, a base layer, an insulating buried layer and a silicon film;
the heavily doped buried layer is located on the silicon film and under the source region and the gate stack;
the surface active layer is located on the heavily doped buried layer;
the gate stack is located on the surface active layer;
the sidewall spacers are located on sidewalls of the gate stack; and
the source region and the drain region, which are embedded into the surface active layer, are located on both sides of the gate stack, and wherein the source region overlaps with the heavily doped buried layer.

11. The semiconductor structure of claim 10, wherein the materials of the heavily doped buried layer are Si, Ge or SiGe, the doping concentration is 10¹⁸-10²⁰ cm⁻³, and the heavily doped buried layer is P-type doped for NMOS and N-type doped for PMOS.

12. The semiconductor structure of claim 10, wherein the materials of the surface active layer are Si, Ge or SiGe, the doping concentration is 10¹⁵-10¹⁸ cm⁻³, and the surface active layer is P-type doped for NMOS and N-type doped for PMOS.

13. The semiconductor structure of claim 10, wherein a silicon film is provided between the drain region and the insulating buried layer, and the doping concentration of the silicon film is smaller than the doping concentration of the heavily doped buried layer.

14. The method of claim 2, wherein at step (a), the materials of the heavily doped buried layer are Si, Ge or SiGe, and the doping concentration is 10¹⁸-10²⁰ cm⁻³, and the heavily doped buried layer is P-type doped for NMOS and N-type doped for PMOS.

15. The method of claim 3, wherein at step (a), the materials of the surface active layer are Si, Ge or SiGe, and the doping concentration is 10¹⁵-10¹⁸ cm⁻³, and the surface active layer is P-type doped for NMOS and N-type doped for PMOS.
